(19) United States
(12) Patent Application Publication
(10) Pub. No.: US 2025/0374527 A1
(43) Pub. Date: Dec. 4, 2025

(54) SEMICONDUCTOR DEVICE

(71) Applicant: Fujian Jinhua Integrated Circuit Co., Ltd., Quanzhou City (CN)

(72) Inventor: Li-Wei Feng, Quanzhou City (CN)

(73) Assignee: Fujian Jinhua Integrated Circuit Co., Ltd., Quanzhou City (CN)

(21) Appl. No.: 18/817,232

(22) Filed: Aug. 28, 2024

(30) Foreign Application Priority Data
Jun. 3, 2024 (CN) 202410711058.0

(51) Int. Cl. H10B 12/00; H01L 29/66

(52) U.S. Cl. CPC H10B 12/482; H10B 12/315; H10B 12/485; H10D 64/021

(57) ABSTRACT

The present disclosure provides a semiconductor device including a substrate, a plurality of gate line structures and a plurality of plug structures, a metal silicide layer, a plurality of pads, and a plurality of pad isolations. The gate line structures and the plug structures are alternately disposed on the substrate. The metal silicide layer is disposed on the plug structures to physically contact the plug structures. The pads are disposed on the metal silicide layer, to physically contact the metal silicide layer. The pad isolations are individually disposed between the pads to physically contact sidewalls of the plug structures and the metal silicide layer. Thus, the semiconductor device is allowable to obtain an improved component and function, to achieve better performance.

### BACKGROUND OF THE INVENTION

### 1. Field of the Invention

The present disclosure relates to a semiconductor device, and more particularly to a semiconductor device having a gate line structure.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

It is one of the primary objectives of the present disclosure to provide a semiconductor device, where pad isolations are disposed between pads to include a bottommost surface being lower than the metal silicide layer, such that, the pad isolations enable to avoid any possible contact between the pads and gate line structures. In this way, through the arrangement of the pad isolations, the short circuit issue between the plug structures and the gate line structures caused by structural defects can be improved, thereby improving the component efficiency and operation performance of the semiconductor device.

To achieve the purpose described, the present disclosure provides a semiconductor device including a substrate, a plurality of gate line structures and a plurality of plug structures, a metal silicide layer, a plurality of pads, and a plurality of pad isolations. The gate line structures and the plug structures are alternately disposed on the substrate. The metal silicide layer is disposed on the plug structures to physically contact the plug structures. The pads are disposed on the metal silicide layer, to physically contact the metal silicide layer. The pad isolations are individually disposed between the pads to physically contact sidewalls of the plug structures and the metal silicide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic cross-sectional diagram illustrating a semiconductor device according to a first embodiment of the present disclosure.

FIG. 2 is a schematic cross-sectional diagram illustrating a semiconductor device according to a preferable embodiment of the present disclosure.

FIG. 3 to FIG. 7 are schematic diagrams illustrating a method of fabricating a semiconductor device according to a preferably embodiment of the present disclosure, wherein:

FIG. 3 is a cross-sectional view of a semiconductor device after forming gate line structures;

FIG. 4 is a cross-sectional view of a semiconductor device after forming plug structures;

FIG. 5 is a cross-sectional view of a semiconductor device after forming a metal silicide layer;

FIG. 6 is a cross-sectional view of a semiconductor device after forming a conductive material layer; and

FIG. 7 is a cross-sectional view of a semiconductor device after performing a photolithography process.

FIG. 8 is a schematic cross-sectional diagram illustrating a semiconductor device according to a second embodiment of the present disclosure.

FIG. 9 is a schematic cross-sectional diagram illustrating a semiconductor device according to a third embodiment of the present disclosure.

FIG. 10 is a schematic cross-sectional diagram illustrating a semiconductor device according to a fourth embodiment of the present disclosure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

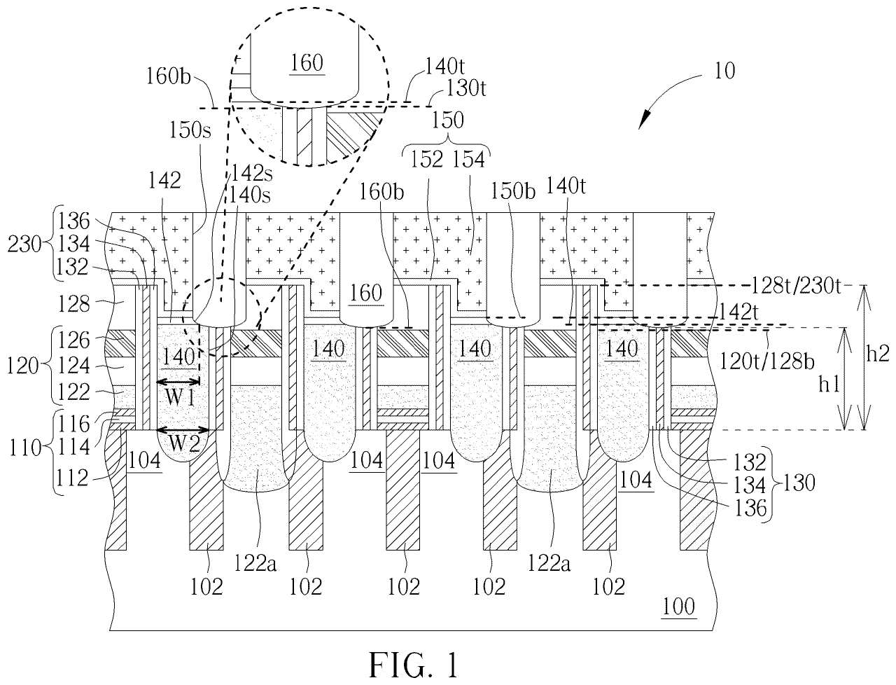

Please refer to FIG. 1, which is a schematic cross-sectional view of a semiconductor device 10 according to a first embodiment of the present disclosure. The semiconductor device 10 includes a substrate 100, a plurality of gate line structures 120 and a plurality of plug structures 140, a metal silicide layer 142, a plurality of pads 150 and a plurality of pad isolations 160. The substrate 100 includes for example, a silicon substrate, a silicon-containing substrate, an epitaxial silicon substrate, a silicon-on-insulator substrate or other suitable materials, but is not limited thereto. The substrate 100 further includes a plurality of shallow trench isolations (STIs) 102 (for example including silicon oxide) and a plurality of active areas (AAs) 104 disposed therein. The gate line structures 120 and the plug structures 140 are alternately disposed on the substrate 100, and the metal silicide layer 142 and one of the pads 150 are further disposed in sequence on each of the plug structures 140. The metal silicide layer 142 physically contacts each of the plug structures 140, and the pad 150 physically contact the metal silicide layer 142. In one embodiment, each of the pads 150 for example includes a barrier layer 152 and a metal layer 154 stacked in sequence. The barrier layer 152 conformally overlays each plug structure 140 and additionally covers a gate-line capping layer 128 of each of the gate structures 120, with the barrier layer 152 for example including a conductive barrier material like titanium and/or titanium nitride, tantalum and/or tantalum nitride. The metal layer 154 overlays the barrier layer 152, and for example includes a low-resistant conductive material like copper, aluminum, tungsten, or other suitable material, but not limited thereto.

It is noted that, the pad isolations 160 are respectively disposed between two adjacent ones of the pads 150, to physically contact the sidewall 150s of each pad 150, the sidewall 142s of the metal silicide layer 142, and a portion of the sidewall 142s of each plug structure 140, to effectively isolate the pads 150 from other components such as the gate line structures 120 adjacent thereto. In one embodiment, the pad isolations 160 for example include an insulating material like silicon nitride or silicon carbonitride, but not limited thereto. In this way, through the arrangements of the pad isolations 160, the possible short circuit issues between the plug structures and the gate line structures caused by structural defects due to continuously increased cell-density will be improved, thereby enhancing the function and the operation of the semiconductor device 10.

Precisely speaking, the gate line structures 120 each include a semiconductor layer 122, a barrier layer 124, and a metal layer 126 stacked in sequence from bottom to top. The semiconductor layer 122 for example includes a semiconductor material such as doped polysilicon and doped amorphous silicon, the barrier layer 124 for example includes a conductive barrier material such as titanium and/or titanium nitride, tantalum and/or tantalum nitride, and the metal layer 126 for example includes copper, aluminum, tungsten or any other suitable low-resistivity conductive material, and the gate-line capping layer 128 for example includes an insulating material like silicon oxide, silicon nitride or silicon oxynitride, but not limited thereto. The gate-line structures 120 are principally disposed on a dielectric layer 110 overlaying the substrate 100, with a portion of the semiconductor layer 122 being penetrated through the dielectric layer 110 and extended into the substrate 100 to serve as a contact 122a physically contacting a corresponding one of the active areas 104. In one embodiment, the dielectric layer 110 for example includes a silicon oxide layer 112, a silicon nitride layer 114 and a silicon oxide layer 116 stacked in sequence and have an oxide-nitride-oxide (ONO) structure, but not limited thereto.

The topmost surface 120t of each gate line structure 120 and the bottommost surface 128b of the gate-line capping layer 128 disposed above the gate line structure 120 are coplanar with each other, and the bottommost surface 160b of each of the pad isolations 160 is preferably higher than the topmost surface 120t of each gate line structure 120 and the bottommost surface 128t of the gate-line capping layer 128 overlaying each gate line structure 120. That is, the bottom of each of the pad isolations 160 further extends into the gate-line capping layer 128 on each gate line structure 120, without contacting the bottommost surface 128t of the gate-line capping layer 128, such that, each pad isolation 160 is partially disposed in the gate-line capping layer 128, for effectively isolating the possible contact between the topmost surface 120t of each gate line structure 120 and the bottommost surface 150b of each pads 150. On the other hand, the bottom of each pad isolation 160 is also partially extended into each plug structure 140, so that, the topmost surface 140t of each plug structure 140 is preferably higher than the bottommost surface 160b of each pad isolation 160 and the topmost surface 120t of each gate line structure 120. Also, a maximum width w1 of the metal silicide layer 142 is smaller than a maximum width w2 of each plug structure 140. Accordingly, the tip 142t of the metal silicide layer 142 and each pad 150 which are sequentially disposed over each plug structure 140 will also be higher than the bottommost surface 160b of each pad isolation 160 and the topmost surface 120t of each gate line structure 120, with each pad isolation 160 simultaneously contacting and overlaying the sidewalls 150s of each pad, the sidewalls 142s of the metal silicide layer 142, and the partial sidewall 140s of each plug structure 140 for effectively isolating each gate line structure 120 from in direct contact with the corresponding pad 150 and the corresponding plug structure 140.

Further in view of FIG. 1, the semiconductor device 10 further includes a first spacer structure 130 and a second spacer structure 230 respectively disposed at two sides of each gate line structure 120. The upper portion of the first spacer structure 130 physically contacts the bottommost surface 160b of each pad isolation 160, to have a relative lower height h1 above the substrate 100. The tip 130t of the first spacer structure 130 is for example lower than the topmost surface 140t of each gate structure 140, and is higher than the topmost surface 120t of each gate line structure 120 and the bottommost surface 160b of each pad isolation 160. The second spacer structure 230 is disposed between two adjacent ones of the pad isolations 160, without in directly contact with any pad isolation 160, to have a relative greater height h2 above the substrate 100. The tip 230t of the second spacer structure 230 is higher than the tip 142t of the metal silicide layer 142, and is coplanar with the topmost surface 128t of the gate-line capping layer 128. In one embodiment, the first spacer structure 130 and the second spacer structure 230 respectively includes a first spacer 132, a second spacer 134, and a third spacer 136 stacked in sequence on the sidewalls of each gate line structure 120 and the gate-line capping layer 128 overlaying each gate line structure 120. The first spacer 132 and the third spacer 136 for example include the same insulating material like silicon nitride or silicon carbonitride, and preferably include the same insulating material as that of the pad isolations 160, and the second spacer 134 for example includes an insulating material being different from that of the first spacer 132 and the third spacer 136, such as being silicon oxide or silicon oxynitride, but not limited thereto.

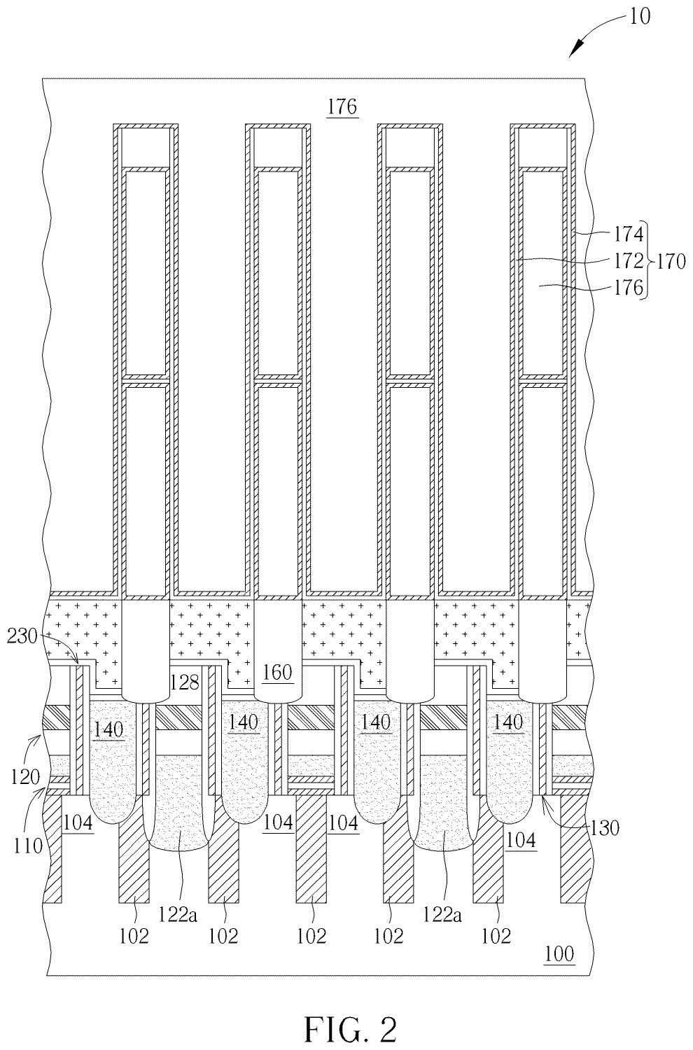

According to the semiconductor device 10 of the present embodiment, the pad isolations 160 are respectively disposed between adjacent ones of the pads 150, with each pad isolation 160 being partially extended into a corresponding plug structure 140 or a corresponding gate-line capping layer 128, so that, each pad isolation 160 is allowable to physically contact the sidewalls 150s of the pads 150, the sidewall 142s of the metal silicide layer 142, and the sidewall 140s of each plug structure 140. Through these arrangements, the bottommost surface 160b of each pad isolation 160 is lower than the tip 142t of the metal silicide layer 142, to electrically isolate each pad 150 in direct contact with the corresponding gate line structure 120 through an effective manner, thereby improving the short circuit issue between the plug structures 140 and the gate line structures 120 caused by structural defects due to continuously increased cell-density. In a preferable embodiment, the semiconductor device 10 may further include a capacitor structure 170 disposed on the pads 150, and the capacitor structure 170 preferably includes a plurality of bottom electrode layers 170, a capacitor dielectric layer 174, and a top electrode layer 176 stacked in sequence. Then, the bottom electrode layers 170, the capacitor dielectric layer 174, and the top electrode layer 176 will together form a plurality of vertical extended capacitors, serving as storage nodes (SNs) of the semiconductor device 10 to electrically connect to the pads 150 serving as storage node pads (SN pads) of the semiconductor device 10, as shown in FIG. 2. Meanwhile, the gate line structures 120 may be served as bit lines (BLs) of the semiconductor device 10, being electrically connected to required components (such as a transistor component) within the substrate 100 through the contacts 122a being configured as bit line contacts (BLCs), and the plug structures 140 may be served as storage node contacts (SNC), being also electrically connected to the required components within the substrate 100. In this way, the semiconductor device 10 of the preferably embodiment enables to function like a dynamic random access memory (DRAM) device, with the capacitors and the transistor components within the substrate 100 together becoming the smallest memory cell of the DRAM array, for receiving the voltage signals from bit lines (namely, the gate line structures 120) and word lines (not shown in the drawings). Thus, the semiconductor device 10 of the present embodiment will therefore gain improved structure and performance, to achieve more optimized operation.

In order to make those having ordinary skills in the art easily understand the semiconductor device 10 according to the present disclosure, a method of fabricating the semiconductor device 10 according to the present disclosure will be further described as follows.

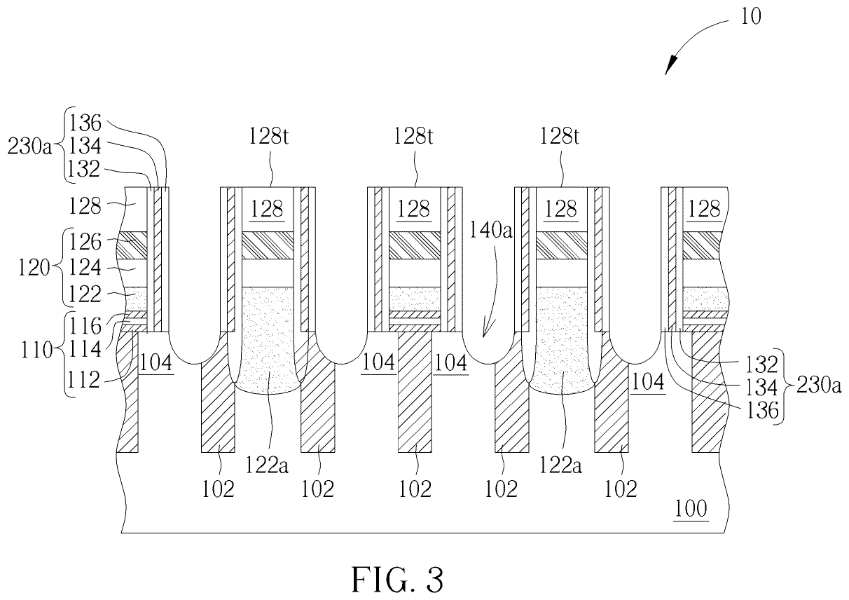

Please refer to FIG. 3 to FIG. 7, which are schematic diagrams illustrating a method of fabricating the semiconductor device 10 according to a preferably embodiment of the present disclosure. Firstly, as shown in FIG. 3, the substrate 100 is provided, and the shallow trench isolations 102 are formed in the substrate 100, to define the active areas 104 within the substrate 100. In one embodiment, the formation of the shallow trench isolations 102 is carried by firstly forming a plurality of shallow trenches (not shown in the drawings) in the substrate 100 via an etching process, followed by filling at least one insulating material (such as including silicon oxide or silicon nitride) in the shallow trenches, to form the shallow trench isolations 102 having a top surface being coplanar with the top surface of the substrate 100, but not limited thereto.

Next, the gate dielectric layer 110, the gate line structures 120 and the gate line capping layer 128 overlaying each gate lien structure 120 are formed on the substrate 110. In one embodiment, the formation of the gate line structures 120 and the gate-line capping layer 128 overlaying each gate lien structure 120 for example include but not limited to the following steps. Firstly, a plurality of openings (not shown in the drawings) is formed in the substrate 100 through the mask layer (not shown in the drawings), to penetrate through the dielectric layer 110 to partially expose corresponding active areas 104 respectively. Then, after removing the mask layer, a semiconductor material layer (not shown in the drawings, for example including a semiconductor material such as doped polysilicon and doped amorphous silicon) is formed on the substrate 100, to fill in the openings, and a barrier material layer (not shown in the drawings, for example including a conductive barrier material such as titanium and/or titanium nitride, tantalum and/or tantalum nitride), a metal material layer (not shown in the drawings, for example including a low-resistance metal material such as copper, aluminum, or tungsten), a capping material layer (not shown in the drawings, for example including an insulating material like silicon oxide, silicon nitride or silicon oxynitride) are sequentially formed on the semiconductor material layer, and a patterning process is performed on the aforementioned stacked layers, to simultaneously form the gate line structures 120 and the gate-line capping layer 128 overlaying each gate line structure 120 as shown in FIG. 1. The gate line structures 120 each include the semiconductor layer 122, the barrier layer 124, and the metal layer 126 stacked in sequence, with a portion of the semiconductor layer 122 filled in the openings to form the contact 122a physically contacting the corresponding active area 104.

Then, as shown in FIG. 3, a spacer structure 230a is formed on each gate line structures 120 and the gate-line capping layer overlaying each gate line structure 120, and which includes the first spacer 132, the second spacer 134 and the third spacer 136 stacked in sequence in the horizontal direction, with the top surface of the spacer structure 230a being coplanar with the top surface 128t of the gate-line capping layer 128. In one embodiment, the fabricating process of the spacer structure 230a includes but not limited to the following steps. Firstly, plural deposition processes and etching back processes are performed on the substrate 100, to sequentially depositing and etching back a first spacer material layer (not shown in the drawing, for example including silicon nitride or silicon carbonitride), a second spacer material layer (not shown in the drawing, for example including silicon oxide or silicon oxynitride), and a third spacer material (not shown in the drawing, for example including silicon nitride or silicon carbonitride) on the gate-line capping layer 128 and the gate line structures 120, thereby forming the spacer structure 230a.

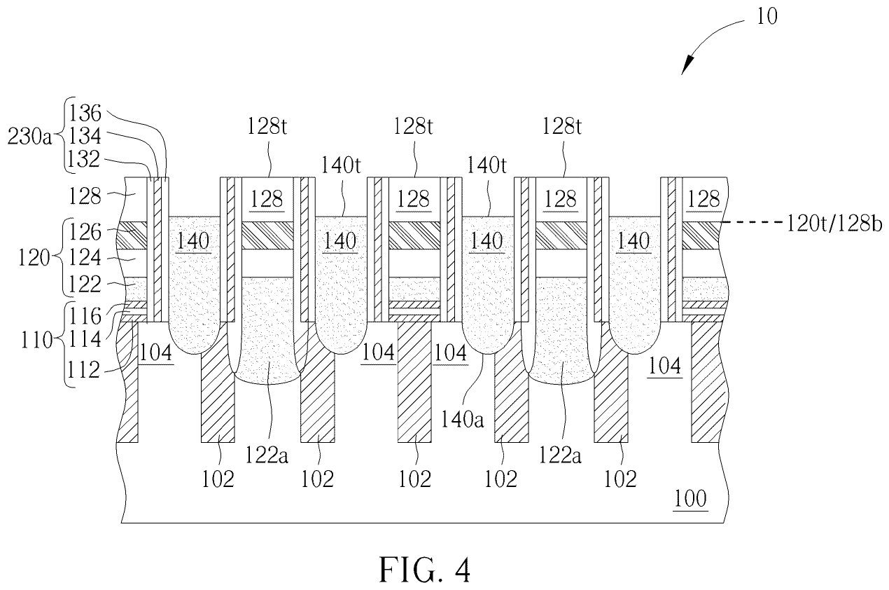

As shown in FIG. 4, a plurality of contact openings 140a is formed in the substrate 100 through another mask layer (not shown in the drawings), by etching a portion of the substrate 100 between adjacent ones of the gate line structures 120. Then, an epitaxial growth process is performed, to form an epitaxial material like silicon, silicon phosphate, silicon germanium, or germanium on the exposed surface of the contact openings 140a, with the epitaxial material filling in the contact openings 140a and further overlaying the space between the adjacent ones of the gate line structures 120, thereby forming the plug structures 140. The top surface 140t of each of the gate structures 140 is preferably higher than the topmost surface 120t of each of the gate line structures 120, and the bottommost surface 128b of the gate-line capping layer 128 overlaying each gate line structure 120, but not limited thereto.

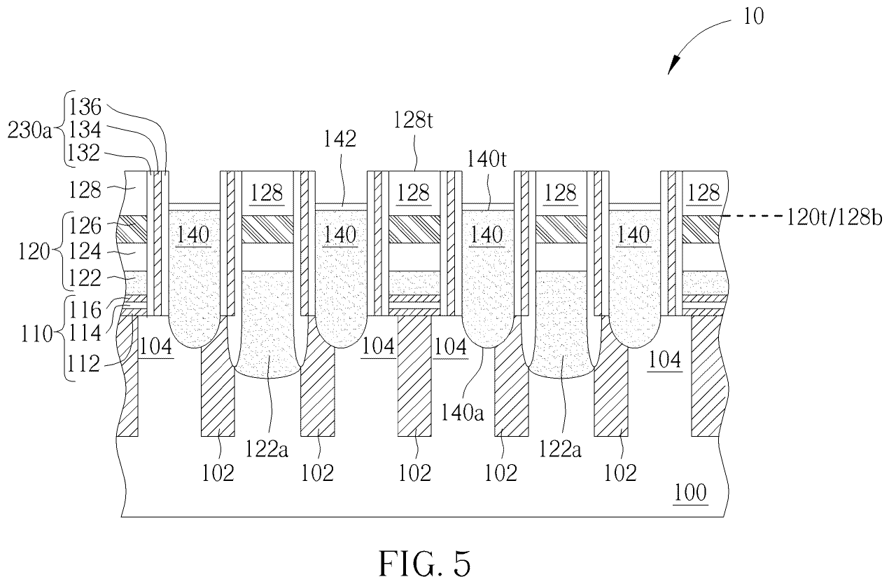

As shown in FIG. 5, a metal silicide process is performed on each plug structure 140, to form the metal silicide layer 142. In one embodiment, the metal silicide process includes but not limited to the following steps. Firstly, a selectively deposition process is performed, to form a metal layer (not shown in the drawings) on each plug structure 140, with the metal layer for example including a metal material suitable to react with silicon, like cobalt, titanium or nickel, preferably for cobalt. Then, a heat treatment is performed, with the metal layer being reacted with a portion of each plug structure 140 underneath, to form the metal silicide layer 142. The metal silicide layer 142 for example includes a metal silicide material such as cobalt disilicide (CoSi₂), titanium silicide (TiSi₂) or nickel silicide (Ni₂Si), and preferably for cobalt disilicide, but not limited thereto. Also, after forming the metal silicide layer 142, the unreacted portion of the metal layer and the another mask layer are completely removed.

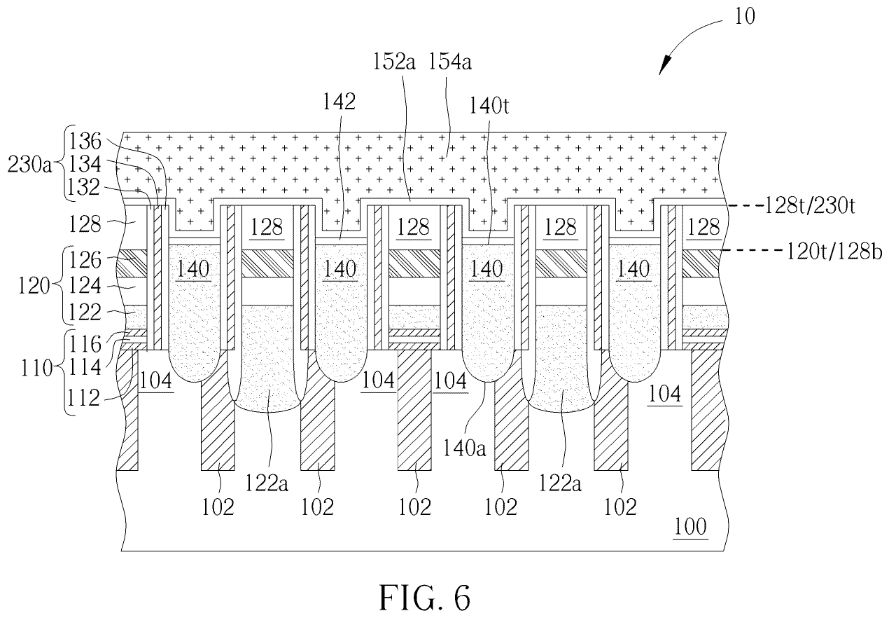

As shown in FIG. 6, at least one deposition process and a planarization process are performed, to sequentially form a barrier material layer 152a (for example including a conductive barrier material like titanium and/or titanium nitride, tantalum and/or tantalum nitride), a metal material layer 154a (for example includes a low-resistant conductive material like copper, aluminum, tungsten, or other suitable material) on the substrate 100. The barrier material layer 152a conformally covers on the plug structures 140, the gate line structures 120, and the spacer structure 230, and the metal material layer 154a fills in the rest space between the adjacent ones of the gate line structures 120, and further overlays the gate-line capping layer 128 and the spacer structures 230a.

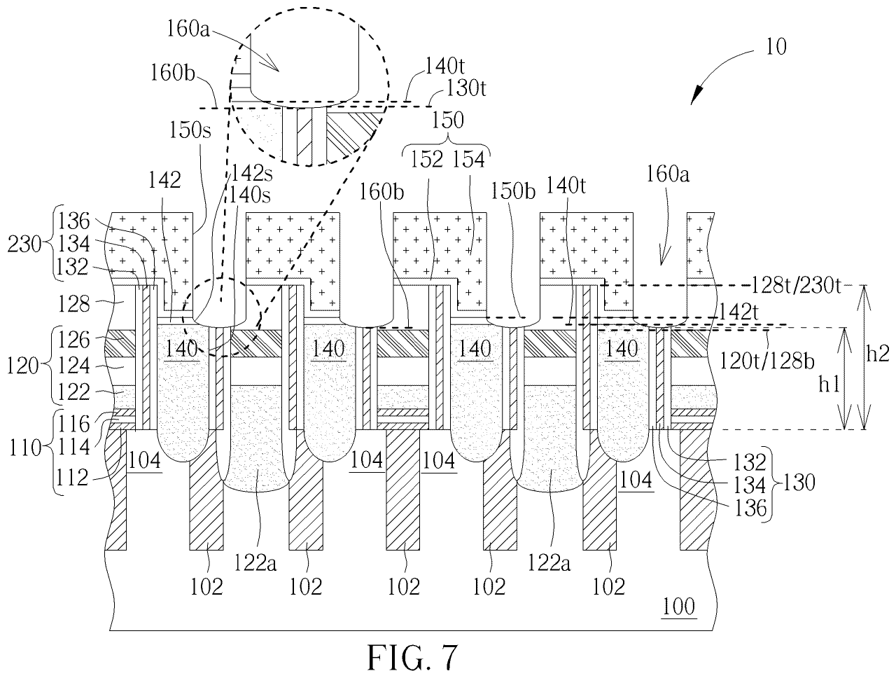

As shown in FIG. 7, a photolithography process is performed on the metal material layer 154a and the barrier material layer 152a through another mask layer (not shown in the drawings), to partially remove the metal material layer 154a and the barrier material layer 152a to form the metal layer 154 and the barrier layer 152. Then, the barrier layer 152 and the metal layer 154 stacked in sequence will together formed each pad 150. It is noted that, while performing the photolithography process, a portion of the gate-line capping layer 128, a portion of the metal silicide layer 142 and a portion of each plug structure 140 are also removed while partially removing the metal material layer 154a and the barrier material layer 152a, due to adjusting the etching conditions thereof, and a plurality of through holes 160 is formed accordingly. The bottom of each of the through holes 160a is preferably extended into the gate-line capping layer 128 and the corresponding plug structure 140, to obtain the bottommost surface 160b being lower than the tip 142t of the metal silicide layer 142, and being higher than the topmost surface 120t of the corresponding gate line structure 120 and the bottommost surface 128t of the gate-line capping layer 128 overlapping the corresponding gate line structure 120, to expose the sidewall 150s of the corresponding pads 150, the sidewall 142s of the metal silicide layer, and the sidewall 140s of the corresponding plug structure 140 at the same time. On the other hand, a portion of the spacer structure 230a is also removed while performing the photolithography process, to form the first spacer structure 130 and the second spacer structure 230 as shown in FIG. 1.

Following these, a deposition process and an etching back process are next performed on the substrate 100, to form an insulating material (for example including an insulating material like silicon nitride or silicon carbonitride) in the through holes 160a, thereby becoming the pad isolations 160 as shown in FIG. 1. Each pad isolation 160 has the bottommost surface 160b being lower than the tip 142t of the metal silicide layer 142, and being higher than the topmost surface 120t of each gate line structure 120. According to the fabricating method of the present embodiment, the pad isolations 160 are formed between the adjacent ones of the pads 150, with each pad isolation 160 being partially extended into the corresponding plug structure 140 and the gate-line capping layer 128, such that, each of the pad isolations 160 enables to physically contact the sidewall 150s of each pads 150, the sidewall 142s of the metal silicide layer 142, and the sidewall 140s of each plug structure 140. In this way, each pad isolation 160 formed through the fabricating method of the present embodiment is allowable to obtain the bottommost surface 160b being lower than the tip 142t of the metal silicide layer 142, to electrically isolate the pads 150 from in direct contact with the gate line structures 120 in a more effective manner, thereby improving the short circuit issue between the plug structures 140 and the gate line structures 120 caused by structural defects due to continuously increased cell-density.

In a preferably embodiment, after forming the semiconductor device 10 as shown in FIG. 1, the capacitor structure 170 as shown in FIG. 2 is further formed over the pads 150, with the capacitor structure 170 including a plurality of bottom electrode layers 170, a capacitor dielectric layer 174, and a top electrode layer 176 stacked in sequence. Then, the bottom electrode layers 170, the capacitor dielectric layer 174, and the top electrode layer 176 will together form a plurality of vertical extended capacitors, serving as storage nodes of the semiconductor device 10 to electrically connect to the pads 150 serving as storage node pads of the semiconductor device 10, as shown in FIG. 2. Meanwhile, the gate line structures 120 being formed through the aforementioned fabricating process may be configured as bit lines of the semiconductor device 10, being electrically connected to required components (such as a transistor component) within the substrate 100 through the contact 122a being configured as a bit line contact, the plug structures 140 also being formed through the aforementioned fabricating process may be configured as storage node contacts also electrically connected to the required components within the substrate 100. In this way, the semiconductor device 10 fabricated in the present embodiment enables to function like the DRAM device, with the capacitors and the transistor components within the substrate together becoming the smallest memory cell of the DRAM array, for receiving the voltage signals from bit lines (namely, the gate line structures 120) and word lines (not shown in the drawings). Thus, the semiconductor device 10 being fabricated accordingly will therefore gain improved structure and performance, to achieve more optimized operation.

A person having ordinary skill in the art should easily understand that the semiconductor device and the fabricating method thereof in the present disclosure may have alternative forms without being limited to the foregoing on the premise of meeting the actual product requirements. Other embodiments or variations of the semiconductor device and the fabricating method thereof according to the present disclosure will be further described below. For avoiding redundant descriptions and readily understanding the embodiments, the following descriptions mainly focus on the differences among embodiments, and will not repeat the similarities. In addition, the same components in various embodiments of the present disclosure are labeled with the same reference numerals, so as to facilitate mutual comparison among various embodiments.

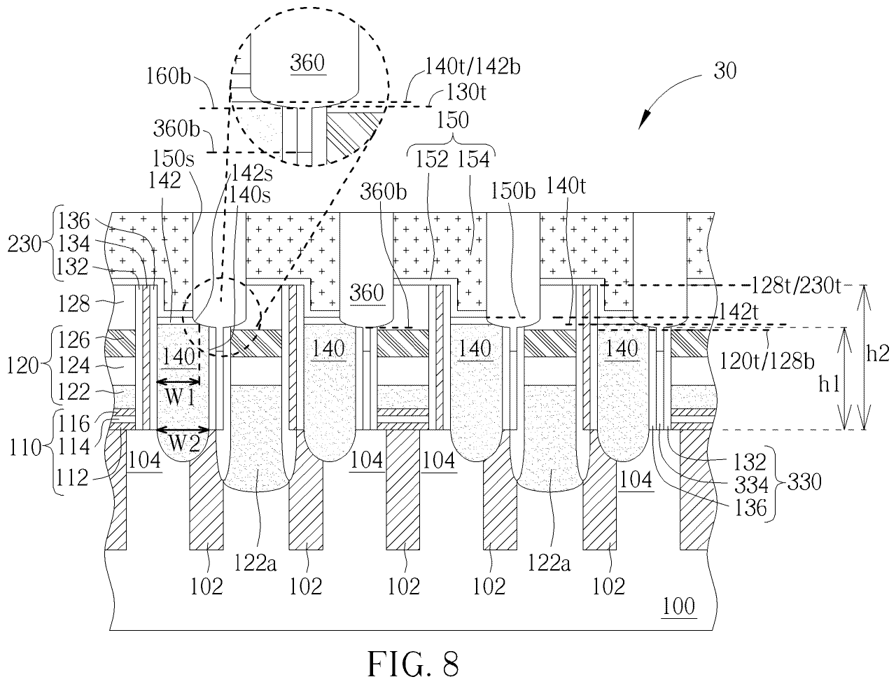

Please refer to FIG. 8, which is a schematic cross-sectional view of a semiconductor device 30 according to the second embodiment of the present disclosure. The semiconductor device 30 in the present embodiment is basically similar to the semiconductor device 10 in the aforementioned embodiment as shown in FIG. 1. The main difference is that the semiconductor device 30 includes pad isolations 360 with each having the bottommost surface 360b lower than the topmost surface 140t of each of the plug structures 140, namely the bottommost surface 142b of the metal silicide layer 142, and the topmost surface 120t of each of the gate line structures 120.

Precisely speaking, while performing a photolithography process on the metal material layer 154a and the barrier material layer 152a in the present embodiment, the second spacer 134 is also removed while partially removing the metal material layer 154a and the barrier material layer 152a, due to adjusting the etching conditions thereof, and an air gap layer 334 is formed between the first spacer 132 and the third spacer 136. Accordingly, the first spacer 132, the air gap layer 336, and the third spacer 136 stacked in sequence in the horizontal direction together form a first spacer structure 330 of the present embodiment. Then, a deposition process and an etching back process are performed on the substrate 100, filling in an insulating material for example including silicon nitride or silicon carbonitride in the through holes 160a as shown in FIG. 7, to form the pad isolations 360 as shown in FIG. 8. The bottom of each of the pad isolations 360 is extended into the air gap layer 334, such that, the bottommost surface 360b of each pad isolation 360 is lower than the topmost surface 140t of the corresponding plug structure 140.

Through the fabricating method of the present embodiment, the pad isolations 360 are also formed between the adjacent pads 150, with each pad isolation 360 being partially extended into the corresponding plug structure 140, the gate-line capping layer 128 and the air gap layer 334, such that, the pad isolations 360 also enable to physically contact the sidewall 150s of each pad 150, the sidewall 142s of the metal silicide layer 142, and the sidewall 140s of the plug structures 140. In this way, each of the pad isolations 360 formed through the fabricating method of the present embodiment is allowable to obtain the bottommost surface 360b being lower than the topmost surface 140t of the corresponding plug structure 140 (namely, the bottommost surface 142b of metal silicide layer 142) and the topmost surface 120t of the gate line structure 120, to electrically isolate the pads 150 from in direct contact with the gate line structures 120 in a more effective manner, and also to obtain an optimized structural stability, thereby improving the short circuit issue between the plug structures 140 and the gate line structures 120 caused by structural defects due to continuously increased cell-density. Thus, the semiconductor device 30 of the present embodiment will therefore gain improved structure and performance, to achieve more optimized operation.

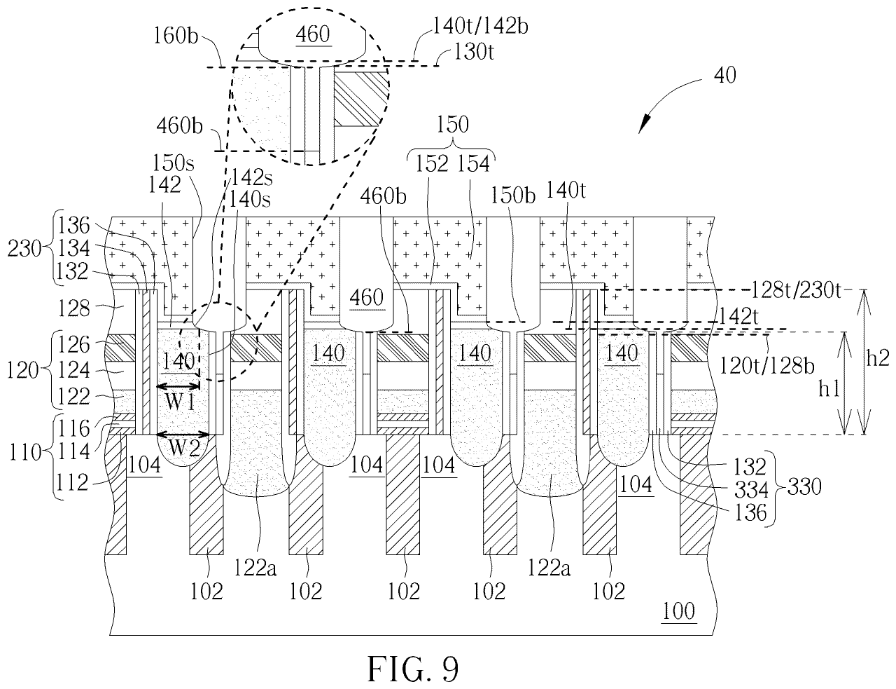

As shown in FIG. 9, a schematic cross-sectional view of a semiconductor device 40 according to the third embodiment of the present disclosure is illustrated. The semiconductor device 40 in the present embodiment is basically similar to the semiconductor device 30 in the aforementioned embodiment. The main difference is that the semiconductor device 40 includes pad isolations 460 with each having the bottommost surface 460b lower than the topmost surface 124t of the barrier layer 124.

Precisely speaking, while performing a photolithography process on the metal material layer 154a and the barrier material layer 152a in the present embodiment, the second spacer 134 is also removed while partially removing the metal material layer 154a and the barrier material layer 152a, due to adjusting the etching conditions thereof, and an air gap layer 334 is formed between the first spacer 132 and the third spacer 136. Then, the pad isolations 360 is formed, with a portion of each pad isolation 360 further extending into the air gap layer 334. Accordingly, the bottommost surface 460b of each pad isolation 460 will be lower than the metal layer 126 of the gate line structures 120. With these arrangements, the semiconductor device 40 fabricated in the present embodiment also includes the pad isolations 460 being partially extended into the corresponding plug structure 140, the gate-line capping layer 128 and the air gap layer 334, such that, the pad isolations 460 also enable to physically contact the sidewalls 150s, 142s, 140s of the pads 150, the metal silicide layer 142 and the plug structures 140 at the same time. Furthermore, the bottommost surface 460b of each pad isolation 460 is lower than the topmost surface 124t of the barrier layer 124, so as to further isolate the pads 150 from in direct contact with the gate line structures 120 in a more effective manner and also to obtain an optimized structural stability, thereby improving the short circuit issue between the plug structures 140 and the gate line structures 120 caused by structural defects due to continuously increased cell-density. Thus, the semiconductor device 40 of the present embodiment still gain improved structure and performance, to achieve more optimized operation.

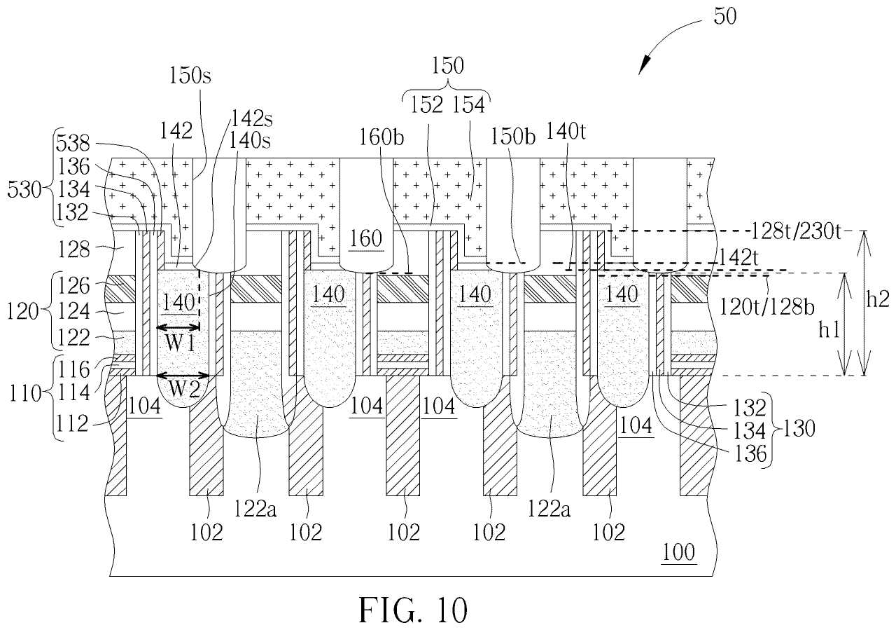

As shown in FIG. 10, a schematic cross-sectional view of a semiconductor device 50 according to the fourth embodiment of the present disclosure is illustrated. The semiconductor device 50 in the present embodiment is basically similar to the semiconductor device 10 in the aforementioned embodiment as shown in FIG. 1. The main difference is that the semiconductor device 50 includes a second spacer structure 530 having the first spacer 132, the second spacer 134, the third spacer 136 and a fourth spacer 538 stacked in sequence in the horizontal direction.

Precisely speaking, while performing the metal silicide process as shown in FIG. 5, a deposition process and an etching back process are additionally performed, to form the fourth spacer 538 on the sidewall of the third spacer 136 of the spacer structure 230a. accordingly, the first spacer 132, the second spacer 134, the third spacer 136 and a fourth spacer 538 stacked in sequence in the horizontal direction will therefore become the second spacer structure 530 of the present embodiment. In one embodiment, the fourth spacer 538 for example includes a material like silicon oxide or silicon oxynitride, but not limited thereto. Following these, the processes as shown in FIG. 5 to FIG. 7 in the aforementioned embodiment are continuously performed then, to form the metal silicide layer 142, the pads 150, and the first spacer structure 130 as shown in FIG. 10. Then, an insulating material is formed on the substrate 100, to fill in the through hole 160a as shown in FIG. 7, to form the pad isolations 160 as shown in FIG. 10.

With these arrangements, the semiconductor device 50 fabricated in the present embodiment also includes the pad isolations 160 being partially extended into the corresponding plug structure 140 and the gate-line capping layer 128, such that, the pad isolations 160 also enable to physically contact the sidewalls 150s, 142s, 140s of the pads 150, the metal silicide layer 142 and the plug structures 140 at the same time, for isolating the pads 150 from in direct contact with the gate line structures 120 in a more effective manner, thereby improving the short circuit issue between the plug structures 140 and the gate line structures 120 caused by structural defects due to continuously increased cell-density. Thus, the semiconductor device 50 of the present embodiment still gain improved structure and performance, to achieve more optimized operation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of gate line structures and a plurality of plug structures, alternately disposed on the substrate;
a metal silicide layer, disposed on each of the plug structures to physically contact each of the plug structures;
a plurality of pads, disposed on the metal silicide layer, to physically contact the metal silicide layer; and
a plurality of pad isolations, individually disposed between the pads to physically contact sidewalls of a corresponding one of the plug structures and the metal silicide layer.

2. The semiconductor device according to claim 1, wherein a bottommost surface of each of the pad isolations is higher than a topmost surface a corresponding one of the gate line structures.

3. The semiconductor device according to claim 2, further comprising:
a gate-line capping layer, disposed on each of the gate line structures, each of the pad isolations is partially disposed in the gate-line capping layer.

4. The semiconductor device according to claim 3, wherein a bottommost surface of each of the pad isolations is higher than a bottommost surface of the gate-line capping layer.

5. The semiconductor device according to claim 1, further comprising:
a first spacer structure, disposed on one side of each of the gate line structures and physically contacting a corresponding one of the pad isolations, wherein a tip of the first spacer structure is lower than a topmost surface of a corresponding one of the plug structures.

6. The semiconductor device according to claim 2, wherein the bottommost surface of each of the pad isolations is lower than a bottommost surface of the pads.

7. The semiconductor device according to claim 1, wherein a bottommost surface of the metal silicide layer is higher than a topmost surface of a corresponding one of the gate line structures.

8. The semiconductor device according to claim 5, further comprising:
a second spacer structure, disposed on another side of each of the gate line structures, wherein a tip of the second spacer structure is higher than a tip of the metal silicide layer.

9. The semiconductor device according to claim 1, wherein a topmost surface of the plug structure is higher than a topmost surface of the gate line structures.

10. The semiconductor device according to claim 1, wherein a bottommost surface of the pads is higher than a topmost surface of the gate line structures.

11. The semiconductor device according to claim 8, wherein the pad isolations physically contact the tip of the first spacer structure.

12. The semiconductor device according to claim 11, wherein the second spacer structure is disposed between two adjacent ones of the pad isolations.

13. The semiconductor device according to claim 8, wherein the first spacer structure and the second spacer structure respectively comprises a first spacer, a second spacer and a third spacer sequentially disposed on a sidewall of each of the gate line structures, and the first spacer and the third spacer comprise a same material as that of the pad isolations.

14. The semiconductor device according to claim 1, wherein a maximum width of the metal silicide layer is smaller than a maximum width of a corresponding one of the plug structures.

15. The semiconductor device according to claim 1, wherein a bottommost surface of one of the pad isolations is lower than a tip of the metal silicide layer.

16. The semiconductor device according to claim 1, wherein a bottommost surface of one of the pad isolations is lower than a topmost surface of a corresponding one of the gate line structures.

17. The semiconductor device according to claim 16, wherein each of the gate line structures comprises a semiconductor layer, a barrier layer and a metal layer stacked in sequence, and the bottommost surface of the one of the pad isolations is lower than a topmost surface of the barrier layer.

18. The semiconductor device according to claim 5, wherein the first spacer structure comprises a first spacer, an air gap layer and a third spacer stacked in sequence, and a topmost surface of a corresponding one of the pad isolations physically contacts the air gap layer.
